(19) United States
(12) Patent Application Publication
(10) Pub. No.: US 2025/0029938 A1
(43) Pub. Date: Jan. 23, 2025

(54) FUNCTIONAL SUBSTRATE AND METHOD FOR MANUFACTURING SAME

(71) Applicants: Beijing BOE Optoelectronics Technology Co., Ltd., Beijing (CN); BOE Technology Group Co., Ltd., Beijing (CN)

(72) Inventors: Yifan WU, Beijing (CN); Yue LI, Beijing (CN); Yuelei XIAO, Beijing (CN); Qichang AN, Beijing (CN); Yulin FENG, Beijing (CN); Xue CAO, Beijing (CN); Kidong HAN, Beijing (CN); Huiying LI, Beijing (CN); Jingshu ZHANG, Beijing (CN); Xiaodong LI, Beijing (CN); Biqi LI, Beijing (CN)

(21) Appl. No.: 18/280,978

(22) PCT Filed: Dec. 16, 2022
(86) PCT No.: PCT/CN2022/139586

§ 371 Date: Sep. 8, 2023

(51) Int. Cl. H01L 23/64; H01L 21/48; H01L 23/15; H01L 23/498; H05K 1/03; H05K 1/11; H05K 3/40

(52) U.S. Cl. CPC H01L 23/645; H01L 21/486; H01L 23/15; H01L 23/49827; H01L 23/49838; H05K 1/0306; H05K 1/115; H05K 3/4038; H05K 2201/09509; H05K 2201/10015; H05K 2201/1003

(57) ABSTRACT

The present disclosure provides a functional substrate and a preparation method thereof, and belongs to the technical field of passive devices. A functional substrate of the present disclosure has a central region and a peripheral region surrounding the central region; the functional substrate includes: a dielectric substrate including a first surface and a second surface opposite to each other in a thickness direction thereof; the dielectric substrate includes functional holes and anchor holes each at least penetrating through the first surface; wherein the functional holes are located in the central region and the anchor holes are located in the peripheral region; the first connection structure is in the functional hole, the second connection structure is in the anchor hole, and the first connection structure and the second connection structure are made of the same material.

This is a National Phase Application filed under 35 U.S.C. 371 as a national stage of PCT/CN2022/139586, filed Dec. 16, 2022, the content of which is hereby incorporated by reference in its entirety.

### FIELD OF THE PRESENT DISCLOSURE

The present disclosure relates to the technical field of passive devices, and in particular, to a functional substrate and a method for manufacturing the same.

### BACKGROUND OF THE PRESENT DISCLOSURE

Semiconductor devices including metallized through holes, such as three-dimensional inductors, adapter plates, package substrates, integrated passive devices, generally include metal layers with a thickness of several micrometers or even tens of micrometers, and the manufacture methods thereof generally include ion sputtering (sputter) and copper electroplating processes. During the manufacturing and using of the device, since a high-temperature process or strong mechanical impact is carried out, a film separation (peeling) phenomenon may occur when the bonding force between the metal layer and the base substrate is poor, so that the performance of the device is influenced, and even the device fails. Generally, the dielectric layer may be manufactured at a temperature above 200° C., the device is packaged through a reflow soldering process at a temperature above 240° C., and the stress generated during the electroplating process is released at a high temperature, so that the device may deform. In addition, the edge film layers of the device tend to separate during cutting and transferring processes.

### SUMMARY OF THE PRESENT DISCLOSURE

In order to solve at least one of the technical problems existing in the prior art, the present disclosure provides a functional substrate and a method for manufacturing the same.

As a first aspect, an embodiment of the present disclosure provides a functional substrate having a central region and a peripheral region surrounding the central region; wherein the functional substrate includes: a dielectric substrate including a first surface and a second surface opposite to each other in a thickness direction of the dielectric substrate; wherein the dielectric substrate has a functional hole and an anchor hole each at least penetrating through the first surface, the functional hole is in the central region, and the anchor hole is in the peripheral region; and a first connection structure and a second connection structure, wherein the first connection structure is in the functional hole, the second connection structure is in the anchor hole, and the first connection structure and the second connection structure are made of a same material.

An orthographic projection of the functional hole on a plane where the first surface is located has a diameter of D; and for each of the anchor hole, a distance between a center of an orthographic projection of the anchor hole on the plane where the first surface is located and a center of an orthographic projection of any one of the functional hole on the plane where the first surface is located is not less than 2D.

For each of the anchor hole, a minimum distance from an edge of the anchor hole to an edge of the dielectric substrate is not less than 50 μm.

The functional hole is a through hole penetrating through the second surface; the functional substrate further includes a first connection electrode on the first surface and a second connection electrode on the second surface; the first connection electrode is connected to the second connection electrode through the first connection structure to form a coil structure of a first inductor.

The functional hole is a blind hole; the first connection structure includes a first connection sub-structure and a second connection sub-structure stacked on the first connection sub-structure; the functional substrate further includes a third connection electrode and a fourth connection electrode arranged in sequence on the first surface; the first connection sub-structure is electrically connected to the third connection electrode to form a first electrode plate of a first capacitor, the second connection sub-structure is electrically connected to the fourth connection electrode to form a second electrode plate of the first capacitor, and a first dielectric layer is between the first electrode plate and the second electrode plate of the first capacitor.

The first connection structure in the functional hole defines a first recess portion, a first filling structure is filled in the first recess portion, and a surface of the first filling structure away from the second surface is flush with a surface of the fourth connection electrode away from the second surface.

The functional hole includes a first functional hole and a second functional hole; the first functional hole is a through hole penetrating through the second surface; the second functional hole is a blind hole; the functional substrate further comprises first, third, and fourth connection electrodes on the first surface, and a second connection electrode on the second surface; the first connection electrode is connected to the second connection electrode through a first connection structure in the first functional hole to form a coil structure of a first inductor; and the first connection structure in the second functional hole includes a first connection sub-structure and a second connection sub-structure stacked on the first connection sub-structure; the first connection sub-structure is electrically connected to the third connection electrode to form a first electrode plate of a first capacitor, the second connection sub-structure is electrically connected to the fourth connection electrode to form a second electrode plate of the first capacitor, and a first dielectric layer is between the first electrode plate and the second electrode plate of the first capacitor.

The first connection structure in the second functional hole defines a first recess portion, a first filling structure is filled in the first recess portion, and a surface of the first filling structure away from the second surface is flush with a surface of the fourth connection electrode away from the second surface.

The anchor hole is a through hole penetrating through the second surface; the functional substrate further includes a fifth connection electrode on the first surface and a sixth connection electrode on the second surface; and the fifth connection electrode is connected to the sixth connection electrode through the second connection structure to form a coil structure of a second inductor.

The anchor hole is a blind hole; the second connection structure includes a third connection sub-structure and a fourth connection sub-structure stacked on the third connection sub-structure, the functional substrate further comprises a seventh connection electrode and an eighth connection electrode arranged in sequence on the first surface; the third connection sub-structure is electrically connected to the seventh connection electrode to form a first electrode plate of the second capacitor, the fourth connection sub-structure is electrically connected to the eighth connection electrode to form a second electrode plate of the second capacitor, and a second dielectric layer is between the first electrode plate and the second electrode plate of the second capacitor.

The second connection structure in the anchor hole defines a second recess portion, and a second filling structure is filled in the second recess portion; a surface of the second filling structure away from the second surface is flush with a surface of the eighth connection electrode away from the second surface.

The anchor hole includes a first anchor hole and a second anchor hole; the first anchor hole is a through hole penetrating through the second surface, and the second anchor hole is a blind hole; the functional substrate includes fifth, seventh, eighth connection electrodes on the first surface, and a sixth connection electrode on the second surface; the fifth connection electrode is connected to the sixth connection electrode through a second connection structure in the first anchor hole to form a coil structure of a second inductor; and a second connection structure in the second anchor hole includes a third substructure and a fourth substructure stacked on the third substructure; the third connection sub-structure is electrically connected to the seventh connection electrode to form a first electrode plate of a second capacitor, the fourth connection sub-structure is electrically connected to the eighth connection electrode to form a second electrode plate of the second capacitor, and a second dielectric layer is between the first electrode plate and the second electrode plate of the second capacitor.

The second connection structure in the second anchor hole defines a second recess portion, and a second filling structure is filled in the second recess portion; a surface of the second filling structure away from the second surface is flush with a surface of the eighth connection electrode away from the second surface.

The dielectric substrate includes glass.

As a second aspect, an embodiment of the present disclosure provides a method for manufacturing a functional substrate having a central region and a peripheral region surrounding the central region; wherein the method includes: providing a dielectric substrate having a first surface and a second surface opposite to each other along a thickness direction of the dielectric substrate; forming a functional hole and an anchor hole in the dielectric substrate such that the functional hole and the anchor hole at least penetrate through the first surface, the functional hole is in the central region, and the anchor hole is in the peripheral region; and forming a first connection structure in the functional hole and a second connection structure in the anchor hole.

The functional hole is a through hole; the functional substrate includes a first inductor in a central region, and forming the first inductor includes: forming the first connection structure in the anchor hole; forming a first connection electrode on the first surface of the dielectric substrate; forming a second connection electrode on the second surface, such that the first connection electrode is connected to the second connection electrode through the first connection structure to form a coil structure of the first inductor.

The functional hole is a blind hole; the functional substrate includes a first capacitor in the central region, and forming the capacitor includes: sequentially forming a first electrode plate, a first dielectric layer and a second electrode plate on the first surface; and forming the first connection structure includes sequentially forming a first connection sub-structure and a second connection sub-structure on the first surface such that the first connection sub-structure serves as a portion of a first electrode plate of the first capacitor, and the second connection sub-structure serves as a portion of a second electrode plate of the first capacitor.

After forming the second electrode plate of the first capacitor, the method further includes: filling a first filling structure in a first recess portion, wherein the first recess portion is defined by the first connection structure in the functional hole.

The anchor is a through-hole; the functional substrate includes a second inductor in the central region, forming of the second inductor includes: forming the second connection structure in the anchor hole; forming a fifth connection electrode on the first surface of the dielectric substrate; forming a sixth connection electrode on the second surface, such that the fifth connection electrode is connected to the sixth connection electrode through the second connection structure to form a coil structure of the second inductor.

The anchor is a blind hole; the functional substrate comprises a second capacitor in the central region, and forming the capacitor includes: sequentially forming a first electrode plate, a second dielectric layer and a second electrode plate on the first surface; and forming the second connection structure includes: sequentially forming a third connection sub-structure and a fourth connection sub-structure on the first surface; such that the third connection sub-structure serves as a portion of the first electrode plate of the second capacitor, and the fourth connection sub-structure serves as a portion of the second electrode plate of the second capacitor.

### BRIEF DESCRIPTION OF THE DRAWINGS

FIG. 1 is a schematic diagram showing a structure of a functional structure according to an embodiment of the present disclosure.

FIG. 2 is a schematic diagram showing a structure of a dielectric substrate of the functional substrate shown in FIG. 1.

FIG. 3 is a schematic diagram showing a structure of another functional structure according to an embodiment of the present disclosure.

FIG. 4 is a schematic diagram showing a structure of a dielectric substrate of the functional substrate shown in FIG. 3.

FIG. 5 is a schematic diagram showing a structure of another functional structure according to an embodiment of the present disclosure.

FIG. 6 is a schematic diagram showing a structure of a dielectric substrate of the functional substrate shown in FIG. 5.

FIG. 7 is a schematic diagram showing a structure of another functional structure according to an embodiment of the present disclosure.

FIG. 8 is a schematic diagram showing a structure of a dielectric substrate of the functional substrate shown in FIG. 7.

FIG. 9 is a schematic diagram showing a structure of another functional structure according to an embodiment of the present disclosure.

FIG. 10 is a schematic diagram showing a structure of a dielectric substrate of the functional substrate shown in FIG. 9.

FIG. 11 is a top view of a functional structure according to an embodiment of the present disclosure.

FIG. 12 is a top view of another functional structure of an embodiment of the present disclosure.

FIG. 13 is a schematic diagram showing a structure of a functional substrate of a first example of an embodiment of the present disclosure.

FIG. 14 is a schematic diagram showing a structure of a first inductor according to an embodiment of the present disclosure.

FIG. 15 is a flowchart of a method for manufacturing a functional substrate of a first example according to an embodiment of the present disclosure.

FIG. 16 is a schematic diagram showing a structure of a functional substrate of a second example of an embodiment of the present disclosure.

FIG. 17 is a flowchart of a method for manufacturing a functional substrate of a second example according to an embodiment of the present disclosure.

FIG. 18 is a schematic diagram showing a structure of a functional substrate of a third example according to an embodiment of the present disclosure.

FIG. 19 is a flowchart of a method for manufacturing a functional substrate according to a third example of an embodiment of the present disclosure.

### DETAILED DESCRIPTION OF THE EXEMPLARY EMBODIMENTS

In order to make the technical solutions of the present invention better understood, the present invention will be further described in detail with reference to the accompanying drawings and the detailed description below.

Unless defined otherwise, technical or scientific terms used herein shall have the ordinary meaning as understood by one of ordinary skill in the art to which the present disclosure belongs. The use of “first”, “second”, and the like in the present disclosure is not intended to indicate any order, quantity, or importance, but rather is used to distinguish one element from another. Also, the use of the terms “a”, “an”, or “the” and similar referents do not denote a limitation of quantity, but rather denote the presence of at least one. The word “include” or “comprise”, or the like, means that the element or item preceding the word comprises the element or item listed after the word and its equivalent, but does not exclude other elements or items. The terms “connect” or “couple” and the like are not restricted to physical or mechanical connections, but may include electrical connections, whether direct or indirect. “Upper”, “lower”, “left”, “right”, and the like are used only to indicate relative positional relationships, and when the absolute position of the object being described is changed, the relative positional relationships may also be changed accordingly.

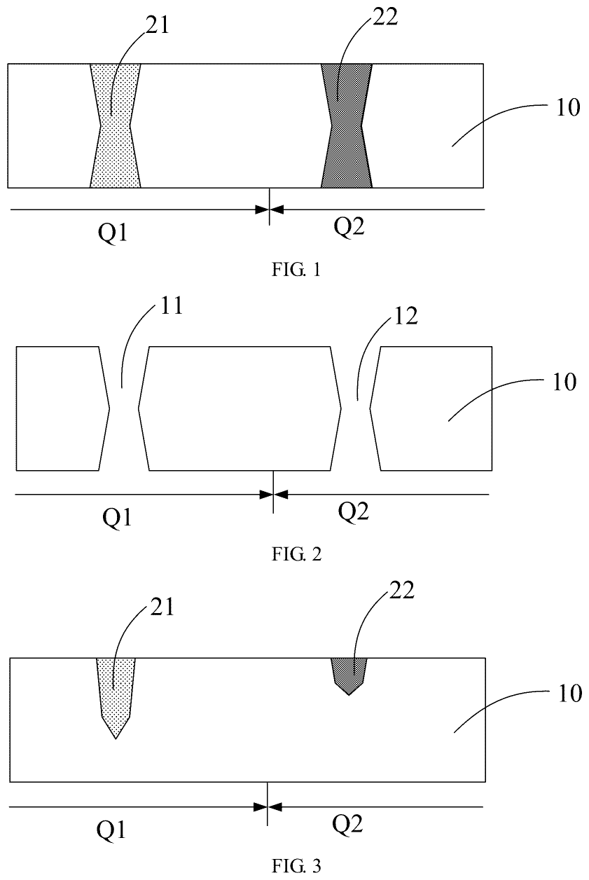

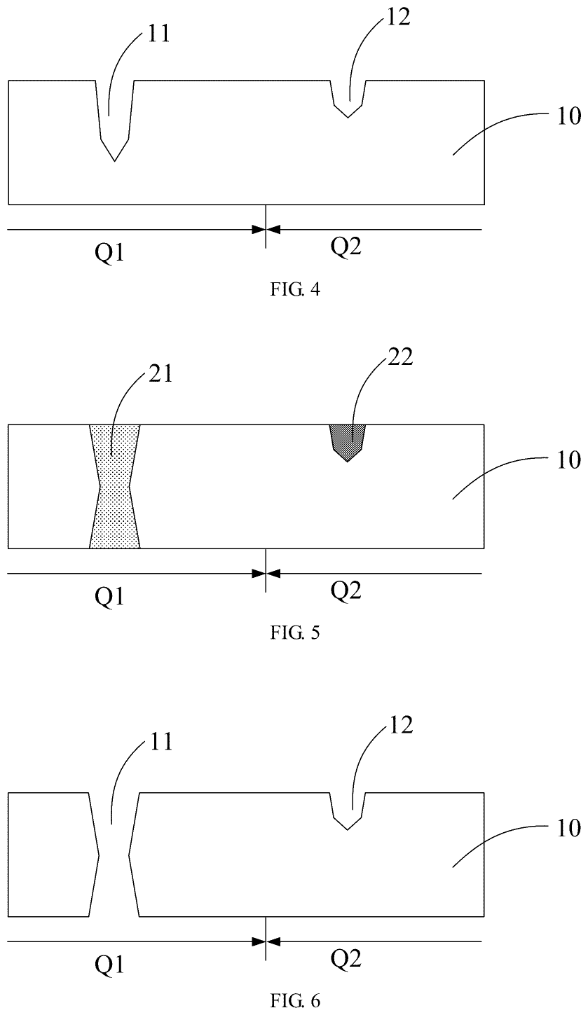

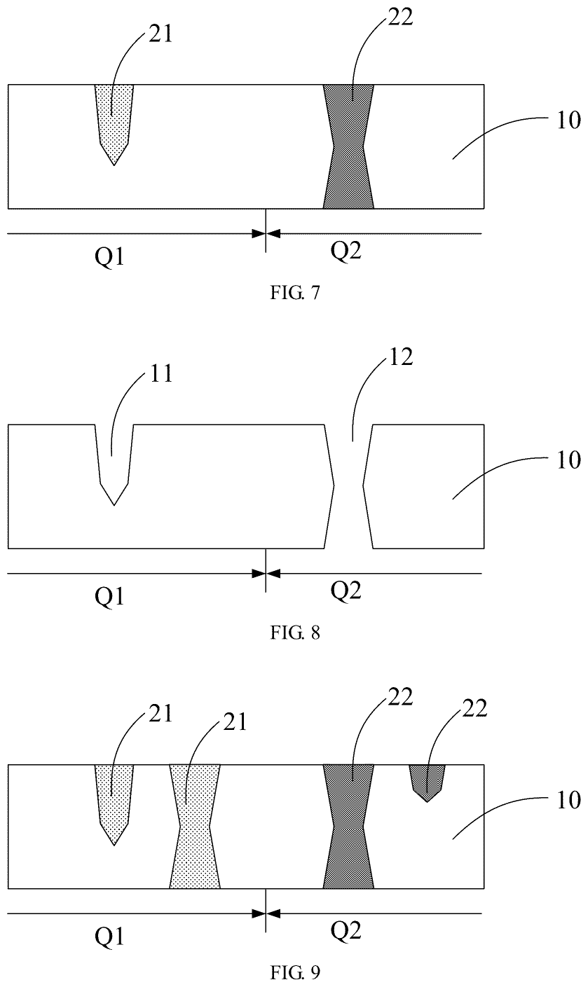

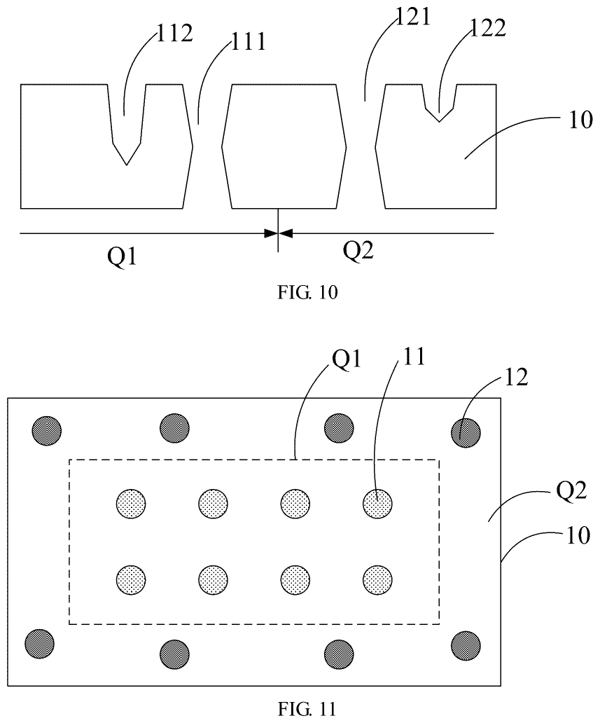

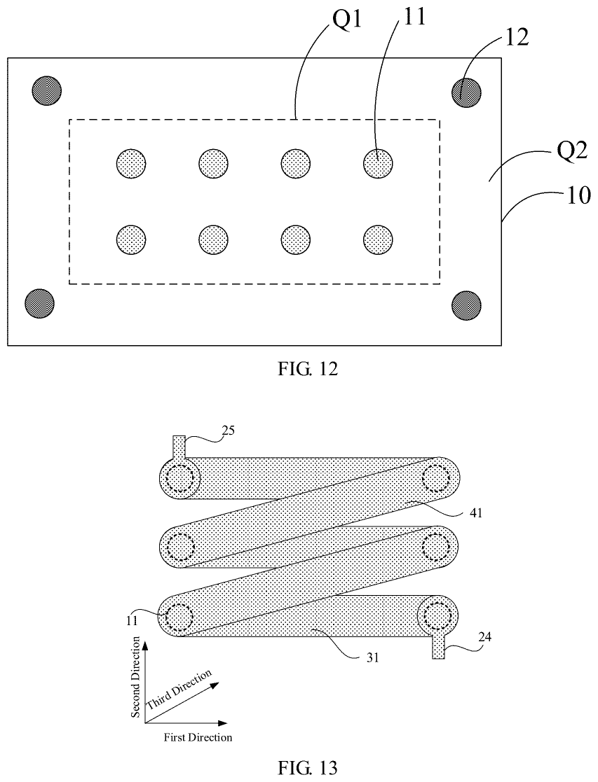

In a first aspect, FIG. 1 is a schematic diagram showing a structure of a functional structure according to an embodiment of the present disclosure. FIG. 2 is a schematic diagram showing a structure of a dielectric substrate of the functional substrate shown in FIG. 1. FIG. 3 is a schematic diagram showing a structure of another functional structure according to an embodiment of the present disclosure. FIG. 4 is a schematic diagram showing a structure of a dielectric substrate of the functional substrate shown in FIG. 3. FIG. 5 is a schematic diagram showing a structure of another functional structure according to an embodiment of the present disclosure. FIG. 6 is a schematic diagram showing a structure of a dielectric substrate of the functional substrate shown in FIG. 5. FIG. 7 is a schematic diagram showing a structure of another functional structure according to an embodiment of the present disclosure. FIG. 8 is a schematic diagram showing a structure of a dielectric substrate of the functional substrate shown in FIG. 7. FIG. 9 is a schematic diagram showing a structure of another functional structure according to an embodiment of the present disclosure. FIG. 10 is a schematic diagram showing a structure of a dielectric substrate of the functional substrate shown in FIG. 9. FIG. 11 is a top view of a functional structure according to an embodiment of the present disclosure. FIG. 12 is a top view of another functional structure according to an embodiment of the present disclosure. As shown in FIGS. 1 to 12, embodiments of the present disclosure provide a functional substrate having a central region Q1 and a peripheral region Q2 surrounding the central region Q1. The functional substrate includes: a dielectric substrate, a first connection structure 21 and a second connection structure 22. The dielectric substrate includes a first surface and a second surface which are oppositely arranged along a thickness direction of the dielectric substrate. The dielectric substrate has a functional hole 11 located in the central region Q1 and an anchor hole 12 located in the peripheral region Q2, and the functional hole and the anchor hole 12 at least penetrate through the first surface; that is, the functional hole 11 and the anchor hole 12 may be blind holes or through holes. The first connection structure 21 is located in the functional hole 11, the second connection structure 22 is located in the anchor hole 12, and the first connection structure 21 and the second connection structure 22 are made of the same material.

The first connection structure 21 is formed in the functional hole 11, so that the functional hole 11 is conductive, and the conductive functional hole 11 is formed in the dielectric substrate. The dielectric substrate may be used in structures such as three-dimensional inductors (in which the functional hole 11 is a through hole), three-dimensional capacitors (in which the functional hole 11 is a blind hole), package substrates, adapter plates, and integrated passive devices.

In the embodiment of the present disclosure, since the anchor hole 12 in the dielectric substrate is formed in the peripheral region Q2 of the functional substrate and the material of the second connection structure 22 in the anchor hole 12 is the same as that of the first connection structure 21 in the functional hole 11, the first connection structure 21 and the second connection structure 22 can be manufacture through one process. Specifically, a conductive layer is formed on the dielectric substrate through an ion sputtering (sputter) process, such that the conductive layer covers the anchor hole 12, and meanwhile covers the functional hole 11. At this time, the conductive layer is anchored through the anchor hole 12 located in the peripheral region Q2, so that the conductive layer can be effectively prevented from being separated from the dielectric substrate, thereby improving the thermal stability of the functional substrate and enriching the electrical properties of the device.

In some examples, the shapes of the functional hole 11 and the anchor hole 12 in the functional substrate may be the same or different. For example, (1) both the functional hole 11 and the anchor hole 12 are through holes, as shown in FIG. 2; (2) both the functional hole 11 and the anchor hole 12 are blind holes, as shown in FIG. 4; (3) one of the functional hole 11 and the anchor hole 12 is a through hole, and the other is a blind hole, as shown in FIGS. 6 and 8; (4) the functional holes 11 include a first functional hole 111 and a second functional hole 112, wherein the first functional hole 111 is a through hole, and the second functional hole 112 is a blind hole; the anchor holes 12 include a first anchor hole 121 and a second anchor hole 122, wherein the first anchor hole 121 is a through hole and the second anchor hole 122 is a blind hole, as shown in FIG. 10. Of course, the shapes of the functional hole 11 and the anchor hole 12 in the functional substrate may further include the following cases: (1) the functional hole 11 includes a first functional hole 111 and a second functional hole 112, wherein the first functional hole 111 is a through hole, the second functional hole 112 is a blind hole, and the anchor hole 12 is a through hole or a blind hole; (2) the anchor hole 12 includes a first anchor hole 121 and a second anchor hole 122, wherein the first anchor hole 121 is a through hole, the second anchor hole 122 is a blind hole, and the functional hole 11 is a through hole or a blind hole.

In some examples, the dielectric substrate may include glass, quartz, silicon, ceramic, organic materials, and the like. In the embodiment of the present disclosure, the dielectric substrate is made of glass. When the dielectric substrate is made of glass, if through holes are formed therein as the functional hole 11 and/or the anchor hole 12, the through holes include but are not limited to, an hourglass shape; if blind holes are formed therein as the functional hole 11 and/or the anchor hole 12, the blind holes include but are not limited to a tapered shape.

The through holes and the blind holes may be formed in various ways in the dielectric substrate, for example, through anyone of the following process: a sand blasting, a photosensitive glass, a focused discharge, a plasma etching, a laser ablation, an electrochemical, or a laser induced etching process, etc. Different methods have different advantages, disadvantages, and application ranges. For example, the sand blasting process has the advantages of simple process, and the through hole/blind hole manufactured through the sand blasting process may have a larger aperture, so that the sand blasting process is only suitable for manufacturing the through hole/blind hole with a aperture larger than 200 μm. The photosensitive glass process has the advantages of simple process and capability of manufacturing through hole/blind hole with high density and high depth-to-width ratio. The focused discharge process has the advantages of fast speed for forming holes. The roughness of the side wall of the through hole/blind hole manufactured through the plasma etching process is small. The laser ablation process has the advantages of capability of manufacturing through holes/blind holes with high density, high depth-to-width ratio, and high roughness. The electrochemical process has the advantages of low cost, simple equipment, fast speed for forming holes and larger diameter of the through hole/blind hole. The laser induced etching process has the advantages of high speed for forming holes, capability of manufacturing through holes/blind holes with high density and high depth-to-width ratio, no damage to the interior of the through hole, and has dis advantages of using an expensive laser equipment.

Further, the laser induced etching process is taken as an example in the embodiments of the present disclosure. Forming the through hole through a laser-induced etching process includes: first of all performing a laser induction modification on a position on a first surface where a through hole needs to be formed by using laser, forming a first sub-hole (i.e., a cone sub-hole) through a wet etching process, performing a laser induction modification on a position on a second surface where the through hole needs to be formed through a laser, and forming a second sub-hole (i.e., a cone sub-hole) through a wet etching process. The first sub-hole and the second sub-hole are correspondingly arranged and are communicated to form the hourglass-shaped through hole. Forming the blind hole through the laser-induced etching process only includes: performing a laser-induced modification on a position on the first surface where the through hole needs to be formed through a laser, and forming the tapered blind hole through a wet etching process.

In some examples, assuming that diameters of orthographic projections of the functional holes 11 on a plane where the first surface of the dielectric substrate is located are equal and are all D; for each of the anchor holes 12, a distance between a center of the orthographic projection of the anchor hole on the plane where the first surface is located and a center of an orthographic projection of anyone of the functional holes 11 on the plane where the first surface is located is not less than 2D. With reasonable setting of the interval between the anchor hole 12 in the peripheral region Q2 and the functional hole 11 in the central region Q1, it can effectively avoid the problem of cracks in the functional hole 11 caused by etching the anchor hole 12, which affects the electrical performance of the device.

In some examples, a distance between an edge of each of the anchor holes 12 and an edge of the dielectric substrate is not less than 50 μm. With reasonably setting of the distance between the anchor hole 12 and the dielectric substrate, it can effectively avoid cracks in the anchor hole 12 in the peripheral region Q2 when the mother board is cut into separated dielectric substrates, which affects the anchoring effect between the anchor hole 12 and the conductive layer.

In some examples, as shown in FIG. 11, the anchor holes 12 may be disposed in the peripheral region Q2, arranged around the display region, and evenly spaced apart from each other. As shown in FIG. 12, the anchor holes 12 may also be formed only at positions of the peripheral region Q2 corresponding to corners of the central region Q1. The specific locations of the anchor holes 12 are not limited in the present disclosure.

The functional substrate in the embodiments of the present disclosure will be described below with reference to specific examples. When the functional holes 11 in the dielectric substrate are through holes, a three-dimensional inductor may be formed by using the through holes. When the functional holes 11 in the dielectric substrate are blind holes, a three-dimensional capacitor may be formed by using the blind holes. When the anchor holes 12 are through holes, the through holes may anchor the conductive layer, or may form a three-dimensional inductor in the peripheral region Q2. When the anchor holes 12 are blind holes, the blind holes may anchor the conductive layer and further may form a three-dimensional capacitor in the peripheral region Q2. Of course, not only the through holes may be used for the formation of the three-dimensional inductor, but also be used for the formation of the wirings on the first surface and the wirings on the second surface, which are within the scope of the embodiments of the present disclosure. Similarly, not only the blind holes may be used for the formation of the three-dimensional inductor, but also be used for the formation of structures such as wirings and resistors. In the embodiment of the present disclosure in which the through holes formed in the dielectric substrate are used for the formation of the three-dimensional inductor, and the blind holes are used for the formation of the three-dimensional capacitor is taken as an example.

The first example is as follows. FIG. 13 is a schematic diagram showing a structure of a functional substrate of a first example in an embodiment of the present disclosure. As shown in FIG. 13, the functional substrate includes a dielectric substrate and a first inductor integrated in a central region Q1 of the dielectric substrate, and a second inductor integrated in a peripheral region Q2 of the dielectric substrate. The dielectric substrate has a plurality of functional holes 11 located in the central region Q1 and a plurality of anchor holes 12 located in the peripheral region Q2, and the functional holes 11 and the anchor holes 12 are through holes. The first inductor includes a first connection structure 21 positioned in the functional hole 11, a first connection electrode 31 positioned on the first surface of the dielectric substrate, and a second connection electrode 41 positioned on the second surface of the dielectric substrate, wherein the first connection electrode 31, the second connection electrode 41, and a first connection via form a coil structure of the first inductor. The second inductor includes a second connection structure 22 positioned in the anchor hole 12, a fifth connection electrode 32 positioned on the first surface of the dielectric substrate, and a sixth connection electrode 42 positioned on the second surface of the dielectric substrate, wherein the fifth connection electrode 32 is electrically connected to the sixth connection electrode 42 through the second connection structure 22 positioned in the anchor hole 12 to form a coil structure of the second inductor.

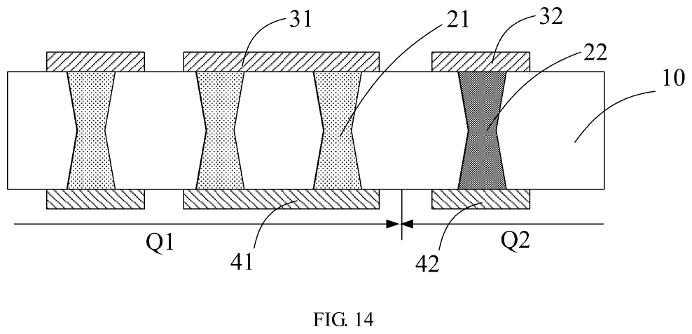

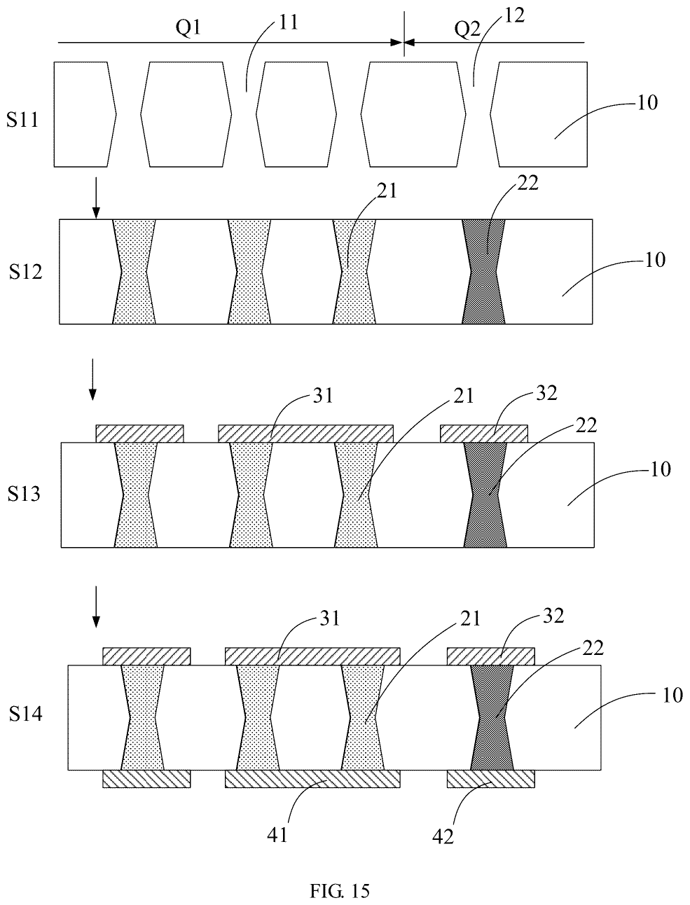

FIG. 14 is a schematic diagram showing a structure of a first inductor according to an embodiment of the present disclosure. As shown in FIG. 14, the first connection electrodes 31 of the first inductor extend in a first direction and are arranged one by one in a second direction, and the second connection electrodes 41 of the inductor extend along a third direction and are arranged one by one along the second direction. The first, second, and third directions are different directions, the first direction and the second direction are perpendicular to each other, and the first direction and the third direction are intersected and not perpendicular to each other in the embodiment of the present disclosure. Of course, the extension directions of the first connection electrode 31 and the second connection electrode 41 may be interchanged, which is within the protection scope of the embodiments of the present disclosure. In addition, in the embodiment in which the inductor includes N first connection electrodes 31 and (N−1) second connection electrodes 41 will be described as an example, where N is an integer greater than and equal to 2. Each of orthographic projections of the first and second ends of the first connection electrode 31 on the dielectric substrate at least overlaps a portion of an orthographic projection of a functional hole 11 on the first dielectric substrate. The first end and the second end of one first connection electrode 31 correspond to different functional holes 11, i.e. the orthographic projection of each first connection electrode 31 on the dielectric substrate at least overlaps a portion of the orthographic projections of two functional holes 11 on the first dielectric substrate. At this time, the first end of the i^{th} second connection electrode 41 of the inductor is connected to the first end of the i^{th} first connection electrode 31 and the second end of the (i+1)^{th} first connection electrode 31 to form an inductor coil, wherein 1≤i≤N−1, and i is an integer.

It should be noted that a first lead terminal 24 is connected to the second end of the 1^{st} first connection electrode 31 of the inductor, and a second lead terminal 25 is connected to the first end of the N^{th} first connection electrode 31. Further, the first and second lead terminals 24 and 25 may be disposed in the same layer and made of the same material as the second connection electrode 41, and in this case, the first lead terminal 24 may be connected to the second end of the 1^{st} first connection electrode 31 through the function hole 11, and correspondingly the second lead terminal 25 may be connected to the first end of the N^{th} first connection electrode 31 through the function hole 11.

In some examples, the first connection electrode 31 of the first inductor and the fifth connection electrode 32 of the second inductor are made of the same material and are disposed in the same layer. That is, the first connection electrode 31 and the fifth connection electrode 32 may be formed in the same process. Similarly, the second connection electrode 41 of the first inductor and the sixth connection electrode 42 of the second inductor are made of the same material and are disposed in the same layer. That is, the second connection electrode 41 and the sixth connection electrode 42 may be formed in the same process.

In some examples, a first protective layer may be further disposed on a side of the first connection electrode 31 away from the first surface, and a second protective layer may be further disposed on a side of the second connection electrode 41 away from the second surface. The first protective layer and the second protective layer may prevent the devices formed on the dielectric substrate from being corroded by water and oxygen.

The functional substrate will be specifically described below with reference to the method for manufacturing the functional substrate. FIG. 15 is a flowchart of a method for manufacturing a functional substrate according to a first example in an embodiment of the present disclosure. As shown in FIG. 15, the method for manufacturing the functional substrate specifically includes steps S11 to S14.

At step S11, providing a dielectric substrate, wherein the dielectric substrate has a plurality of functional holes 11 and a plurality of anchor holes 12 which penetrate through the dielectric substrate along a thickness direction of the dielectric substrate. The functional holes 11 are located in the central region Q1, and the anchor holes 12 are located in the peripheral region Q2.

The functional hole 11 and the anchor hole 12 in the dielectric substrate are through holes, and the through holes in the dielectric substrate may be formed by any one of the sand blasting process, the photosensitive glass process, the focusing discharge process, the plasma etching process, the laser ablation process, the electrochemical process, the laser-induced etching process, and the like, which will not be described herein again.

At step S12, forming a first connection structure 21 in the functional hole 11 and a second connection structure 22 in the anchor hole 12.

In some examples, step S12 may include steps S121 to S124.

At step S121, forming a first conductive layer and a second conductive layer on the first surface and the second surface of the dielectric substrate respectively through a magnetron sputtering process to form a first seed layer and a second seed layer. With the formation of the first conductive layer and the second conductive layer, the inner walls of the functional hole 11 and the anchor hole 12 are each continuously covered.

At step S122, growing the first seed layer and the second seed layer by simultaneously loading current on double sides of the first seed layer and the second seed layer through a double-sided electroplating process, to fill the functional hole 11 and the anchor hole 12.

At step S123, temporarily bonding a carrier on a side, away from the dielectric substrate, of the thickened second seed layer; removing the thickened second seed layer on the first surface through a process including but not limited to a chemical physical polishing (CMP) process; and debonding the carrier. If a thickness of the carrier is thin, the temporarily bonded carrier needs to be reinforced to ensure strength.

At step S124, temporarily bonding the carrier on a side of the first surface of the dielectric substrate; removing the thickened first seed layer on the second surface through a process including but not limited to a chemical physical polishing (CMP) process; and debonding the carrier. Similarly, if the carrier is thin, the temporarily bonded carrier needs to be reinforced to ensure strength.

So far, the first connection structure 21 located in the functional hole 11 and the second connection structure 22 located in the anchor hole 12 are formed.

At step S13, forming a first connection electrode 31 and a fifth connection electrode 32 on the first surface of the dielectric substrate.

In some examples, step S13 may include forming a third conductive layer through a process including, but not limited to, a magnetron sputtering, spin-coating a photoresist, exposing the photoresist with a corresponding mask, denaturing the photoresist by irradiating the photoresist with the ultraviolet light, developing the photoresist, removing the denatured photoresist, and forming a pattern including the first and fifth connection electrodes 31 and 32 through a wet etching process.

At step S14, forming a second connection electrode 41 and a sixth connection electrode 42 on the second surface of the dielectric substrate, wherein the second connection electrode 41 is electrically connected to the first connection electrode 31 through the first connection structure 21 in the functional hole 11 to form a coil structure of a first inductor, and the sixth connection electrode 42 is electrically connected to the fifth connection electrode 32 through the second connection structure 22 in the anchor hole 12 to form a coil structure of a second inductor.

In some examples, step S14 may include forming a fourth conductive layer through a process including but not limited to, a magnetron sputtering process, spin-coating a photoresist, exposing the photoresist with a corresponding mask, denaturing the photoresist by irradiating the photoresist with the ultraviolet light, developing the photoresist, removing the denatured photoresist, and forming a pattern including the second connection electrode 41 and the sixth connection electrode 42 through a wet etching process.

For the functional substrate in the first example, since the anchor hole 12 is formed in the peripheral region Q2 of the dielectric substrate, when the first connection structure 21 is formed, the anchor hole 12 is covered by the first conductive layer and the second conductive layer, so that the separation of the first conductive layer and the second conductive layer from the dielectric substrate during the magnetron sputtering process and the electroplating process, and thereby the influence on the electrical characteristics of the formed first capacitor due to the separation can be effectively avoided. In the first example, the anchor hole 12 is not only used for anchoring the conductive layer, but also used for forming the second inductor coil in the peripheral region Q2 of the dielectric substrate while the first inductor coil is formed, which is equivalent to enlarging the device area of the functional substrate and improving the utilization rate of the dielectric substrate.

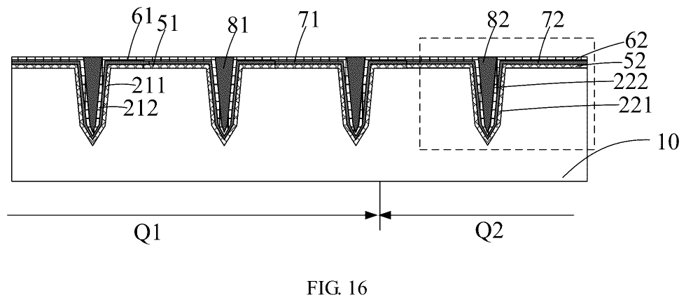

The second example is as follow. FIG. 16 is a schematic diagram showing a structure of a functional substrate in a second example of an embodiment of the present disclosure. As shown in FIG. 16, the functional substrate includes a dielectric substrate, a first capacitor integrated in the central region Q1 of the dielectric substrate, and a second capacitor integrated in the peripheral region Q2 of the dielectric substrate. Of course, the functional substrate may also include integrated passive devices or the like having the first and/or second capacitors. The dielectric substrate has a plurality of functional holes 11 located in the central region Q1, and a plurality of anchor holes 12 located in the peripheral region Q2, and both the functional holes 11 and the anchor holes 12 are blind holes. The first capacitor includes a first electrode plate, a first dielectric layer 71 and a second electrode plate arranged in sequence on a side of the dielectric substrate away from the second surface of the dielectric substrate. The first capacitor includes a first electrode plate, a second dielectric layer 72, and a second electrode plate disposed in sequence on a side of the dielectric substrate away from the second surface of the dielectric substrate.

Specifically, the functional substrate includes a first connection structure 21 located in the functional hole 11, and a third connection electrode 51 and a fourth connection electrode 61 sequentially arranged on a side of the dielectric substrate away from the second surface of the dielectric substrate. The first connection structure 21 includes a first connection sub-structure 211 and a second connection sub-structure 212 arranged in sequence on a side of the dielectric substrate away from the second surface of the dielectric substrate. The first connection sub-structure 211 and the third connection electrode 51 are formed into a one-piece structure to serve as the first electrode plate of the first capacitor, and the second connection sub-structure 212 and the fourth connection electrode 61 serve as the second electrode plate of the first capacitor.

Further, the functional substrate further includes a second connection structure 22 located in the anchor hole 12, and a seventh connection electrode 52 and an eighth connection electrode 62 sequentially arranged on a side of the dielectric substrate away from the second surface of the dielectric substrate. The second connection structure 22 includes a third connection sub-structure 221 and a fourth connection sub-structure 222. The third connection sub-structure 221 and the seventh connection electrode 52 are formed into a one-piece structure to serve as the first electrode plate of the second capacitor, and the fourth connection sub-structure 222 and the eighth connection electrode 62 are formed into a one-piece structure to serve as the second electrode plate of the second capacitor.

Furthermore, the first connection sub-structure 211, the third connection sub-structure 221, the third connection electrode 51, and the seventh connection electrode 52 may be formed as a one-piece structure, that is, the first connection sub-structure 211, the third connection sub-structure 221, the third connection electrode 51, and the seventh connection electrode 52 are disposed in the same layer, made of the same material, and formed in one process. Similarly, the second connection sub-structure 212, the fourth connection sub-structure 222, the fourth connection electrode 61, and the eighth connection electrode 62 may be formed as a one-piece structure, that is, the second connection sub-structure 212, the fourth connection sub-structure 222, the fourth connection electrode 61, and the eighth connection electrode 62 are disposed on the same layer, made of the same material, and formed in one process. The first dielectric layer 71 and the second dielectric layer 72 are formed into a one-piece structure, that is, the first dielectric layer 71 and the second dielectric layer 72 are disposed in the same layer, made of the same material, and formed in one process.

In some examples, since the first connection structure 21 located in the functional hole 11 defines a first recess portion, the first filling structure 81 may be filled in the first recess portion, so that a surface of the first filling structure 81 away from the second surface is flush with a surface of the fourth connection electrode 61 away from the second surface, so as to facilitate formation of subsequent layers. The first filling structure 81 may be made of resin.

Similarly, since the second connection structure 22 located in the anchor hole 12 defines a second recess portion, the second filling structure 82 may be filled in the second recess portion, so that a surface of the second filling structure 82 away from the second surface is flush with a surface of the eighth connection electrode 62 away from the second surface, so as to facilitate formation of subsequent layers. The second filling structure 82 may be made of resin.

In some examples, a first protection layer may further be disposed on a side of the first filling structure 81 away from the first surface. The first protective layer may prevent the devices formed on the dielectric substrate from being corroded by water and oxygen.

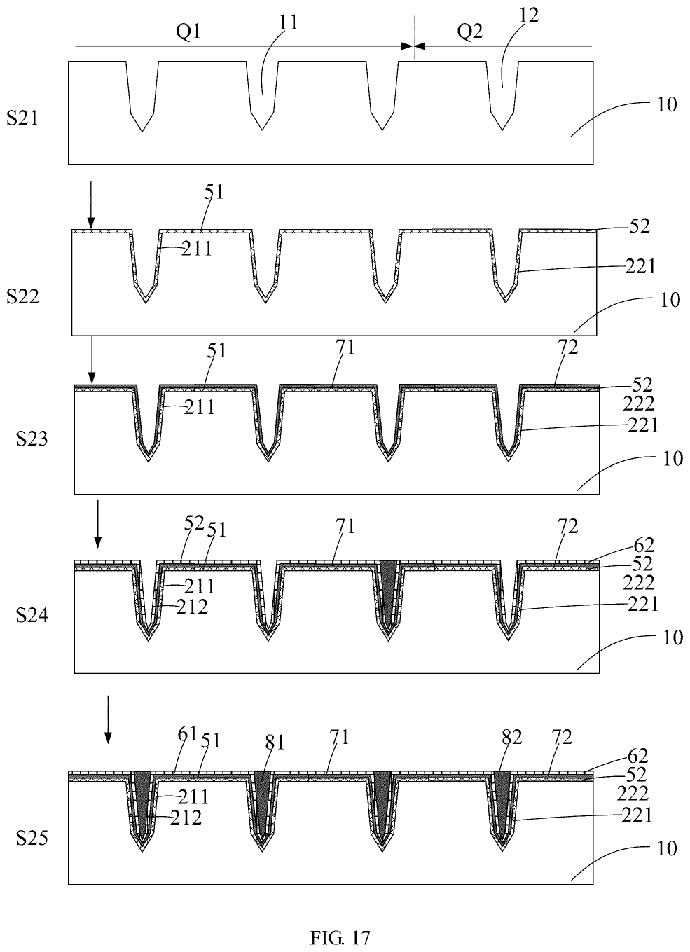

The functional substrate will be specifically described below with reference to the method for manufacturing the functional substrate. FIG. 17 is a flowchart of a method for manufacturing a functional substrate according to a second example of the embodiment of the present disclosure. As shown in FIG. 17, the method for manufacturing the functional substrate specifically includes steps S21 to S25.

At step S21, providing a dielectric substrate having a plurality of functional holes 11 and a plurality of anchor holes 12 penetrating through a part of the dielectric substrate along a thickness direction of the dielectric substrate. The functional holes 11 are located in the central region Q1, and the anchor holes 12 are located in the peripheral region Q2.

The functional hole 11 and the anchor hole 12 in the dielectric substrate are both blind holes, and the blind holes in the dielectric substrate may be formed through any one of a sand blasting process, a photosensitive glass process, a focusing discharge process, a plasma etching process, a laser ablation process, an electrochemical process, a laser-induced etching process, and the like, which will not be described herein again.

At step S22, forming a pattern including the first connection sub-structure 211 of the first connection structure 21, the third connection sub-structure 221 of the second connection structure 22, the third connection electrode 51, and the seventh connection structure, that is, forming a first electrode plate of the first capacitor and a first electrode plate of the second capacitor; wherein the first connection sub-structure 211 is located in the functional hole 11, and the third connection sub-structure 221 is located in the anchor hole 12.

In some examples, the first connection sub-structure 211, the third connection sub-structure 221, the third connection electrode 51, and the seventh connection electrode 52 are formed into a one-piece structure. Step S22 may include but not limited to: forming a first conductive layer through a magnetron sputtering process, spin-coating a photoresist, exposing with a corresponding mask, denaturing the photoresist by irradiating the photoresist with the ultraviolet light, developing the photoresist, removing the denatured photoresist, and forming a pattern including the first connection sub-structure 211, the third connection sub-structure 221, the third connection electrode 51, and the seventh connection electrode 52 through a wet etching process, that is, forming the first electrode plate of the first capacitor and the first electrode plate of the second capacitor.

At step S23, forming a first dielectric layer 71 and a second dielectric layer 72.

In some examples, step S23 may include forming first and second dielectric layers 71 and 72 into a one-piece structure through a Chemical Vapor Deposition (CVD) process. The material of the first and second dielectric layers 71 and 72 formed into the one-piece structure includes but is not limited to, an insulating material such as silicon oxide or silicon nitride.

At step S24, forming a pattern including the second connection sub-structure 212 of the first connection structure 21, the fourth connection sub-structure 222 of the second connection structure 22, the fourth connection electrode 61 and the eighth connection electrode 62, that is, forming the second electrode plate of the first capacitor and the second electrode plate of the second capacitor.

In some examples, the second connection sub-structure 212, the fourth connection sub-structure 222, the fourth connection electrode 61, and the eighth connection electrode 62 are formed as a one-piece structure, and step S24 may include but not limited to: forming a first conductive layer through a magnetron sputtering process, spin-coating a photoresist, performing exposure with a corresponding mask, denaturing the photoresist by irradiating the photoresist with the ultraviolet light, developing the photoresist, removing the denatured photoresist, and forming a pattern including the second connection sub-structure 212, the fourth connection sub-structure 222, the fourth connection electrode 61, and the eighth connection electrode 62 through a wet etching process, that is, forming the second electrode plate of the first capacitor and the second electrode plate of the second capacitor.

At step S25, the first connection structure 21 located in the anchor hole 12 defines a first recess portion, the second connection structure 22 located in the anchor hole defines a second recess portion, forming a first filling structure 81 within the first recess portion, and forming a second filling structure 82 in the second recess portion.

In some examples, step S25 includes forming a filling material in the first and second recess portions through a vacuum plugging process; curing the filling material; and grinding a surface of the filling material flat by using an abrasive belt machine to form the first and second filling structures 81 and 82. The filler material includes but is not limited to resin.

For the functional substrate in the second example, since the anchor hole 12 is formed in the peripheral region Q2 of the dielectric substrate, when the first capacitor is formed, the anchor hole 12 is covered by the first conductive layer and the second conductive layer, so that the separation of the first conductive layer and the second conductive layer from the dielectric substrate during the magnetron sputtering process and the electroplating process, and thereby the influence on the electrical characteristics of the formed first capacitor due to the separation can be effectively avoided. In the second example, the anchor hole 12 is not only used for anchoring the conductive layer, but also used for forming a second capacitor in the peripheral region Q2 of the dielectric substrate while the first capacitor is formed, which is equivalent to enlarging the device area of the functional substrate and improving the utilization rate of the dielectric substrate.

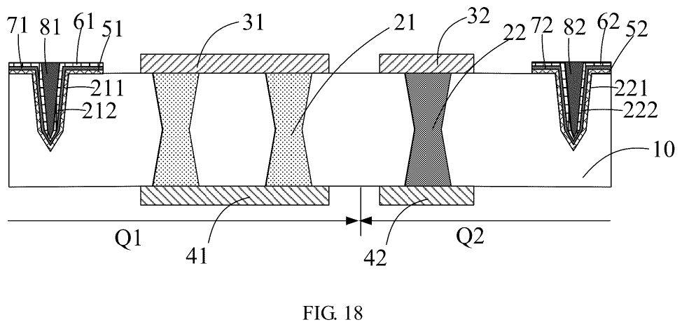

The third example is as follow. FIG. 18 is a schematic diagram showing a structure of a functional substrate in a third example of an embodiment of the present disclosure. As shown in FIG. 18, the functional substrate includes a dielectric substrate, a first inductor and a first capacitor integrated in the central region Q1, and a second inductor and a second capacitor integrated in the peripheral region Q2. The dielectric substrate has a functional hole 11 located in the central region Q1 and an anchor hole 12 located in the peripheral region Q2. The functional holes 11 include a first functional hole 111 and a second functional hole 112, the first functional hole 111 is a through hole, and the second functional hole 112 is a blind hole. The anchor hole 12 includes a first anchor hole 121 and a second anchor hole 122, the first anchor hole 121 is a through hole, and the second anchor hole 122 is a blind hole.

The first inductor includes a first connection structure 21 located in the first functional hole 111, a first connection electrode 31 located on the first surface, and a second connection electrode 41 located on the second surface. The first connection electrode 31 is electrically connected to the second connection electrode 41 through the first connection structure 21 located in the first functional hole 111 to form a coil structure of the first inductor. The second inductor includes the second connection structure 22 located in the second functional hole 112, the fifth connection electrode 32 located on the first surface, and the sixth connection electrode 42 located on the second surface. The fifth connection electrode 32 is electrically connected to the sixth connection electrode 42 through the second connection structure 22 located in the first anchor hole 121, so as to form a coil structure of the second inductor.

In some examples, the first connection electrode 31 of the first inductor and the fifth connection electrode 32 of the second inductor are the same material and are disposed in the same layer. That is, the first connection electrode 31 and the fifth connection electrode 32 may be formed in the same process. Similarly, the second connection electrode 41 of the first inductor and the sixth connection electrode 42 of the second inductor are made of the same material and are disposed in the same layer. That is, the second connection electrode 41 and the sixth connection electrode 42 may be formed in the same process.

The first capacitor includes a first electrode plate, a first dielectric layer 71 and a second electrode plate sequentially arranged on a side of the dielectric substrate away from the second surface of the dielectric substrate. The second capacitor includes a first electrode plate, a second dielectric layer 72, and a second electrode plate arranged in sequence a side of the dielectric substrate away from the second surface of the dielectric substrate.

Specifically, the functional substrate includes a first connection structure 21 located in the second functional hole 112, and a third connection electrode 51 and a fourth connection electrode 61 sequentially arranged on a side of the dielectric substrate away from a second surface of the dielectric substrate. The first connection structure 21 located in the second functional hole 112 includes a first connection sub-structure 211 and a second connection sub-structure 212 arranged in sequence on a side of the dielectric substrate away from the second surface of the dielectric substrate. The first connection sub-structure 211 and the third connection electrode 51 are formed into a one-piece structure to form the first electrode plate of the first capacitor, and the second connection sub-structure 212 and the fourth connection electrode 61 form the second electrode plate of the first capacitor.

Further, the functional substrate further includes a second connection structure 22 located in the second anchor hole 122, and a seventh connection electrode 52 and an eighth connection electrode 62 sequentially arranged on a side of the dielectric substrate away from the second surface of the dielectric substrate. The second connection structure 22 located in the second anchor hole 122 includes a third connection sub-structure 221 and a fourth connection sub-structure 222. The third connection sub-structure 221 and the seventh connection electrode 52 are formed into a one-piece structure to form the first electrode plate of the second capacitor, and the fourth connection sub-structure 222 and the eighth connection electrode 62 are formed into a one-piece structure to form the second electrode plate of the second capacitor.

Furthermore, the first connection sub-structure 211, the third connection sub-structure 221, the third connection electrode 51, and the seventh connection electrode 52 may be formed as a one-piece structure, that is, the first connection sub-structure 211, the third connection sub-structure 221, the third connection electrode 51, and the seventh connection electrode 52 are disposed on the same layer, made of the same material, and formed in one process. Similarly, the second connection sub-structure 212, the fourth connection sub-structure 222, the fourth connection electrode 61, and the eighth connection electrode 62 may be formed into a one-piece structure, that is, the second connection sub-structure 212, the fourth connection sub-structure 222, the fourth connection electrode 61, and the eighth connection electrode 62 are disposed on the same layer, made of the same material, and formed in one process. The first dielectric layer 71 and the second dielectric layer 72 are formed as a one-piece structure, that is, the first dielectric layer 71 and the second dielectric layer 72 are disposed in the same layer, made of the same material, and formed in one process.

In some examples, since the first connection structure 21 located in the second functional hole 112 defines a first recess portion, the first filling structure 81 may be filled in the first recess portion, so that a surface of the first filling structure 81 away from the second surface is flush with a surface of the fourth connection electrode 61 away from the second surface, so as to facilitate the formation of subsequent layers. The first filling structure 81 may be made of resin.

Similarly, since the second connection structure 22 located in the second anchor hole 122 defines a second recess portion, the second filling structure 82 may be filled in the second recess portion, so that a surface of the second filling structure 82 away from the second surface is flush with a surface of the eighth connection electrode 62 away from the second surface, so as to facilitate the formation of subsequent layers. The second filling structure 82 may be made of resin.

In some examples, a first protective layer may be further disposed on a side of the first connection electrode 31 away from the first surface, and a second protective layer may be further disposed on a side of the second connection electrode 41 away from the second surface. The first protective layer and the second protective layer may prevent the devices formed on the dielectric substrate from being corroded by water and oxygen.

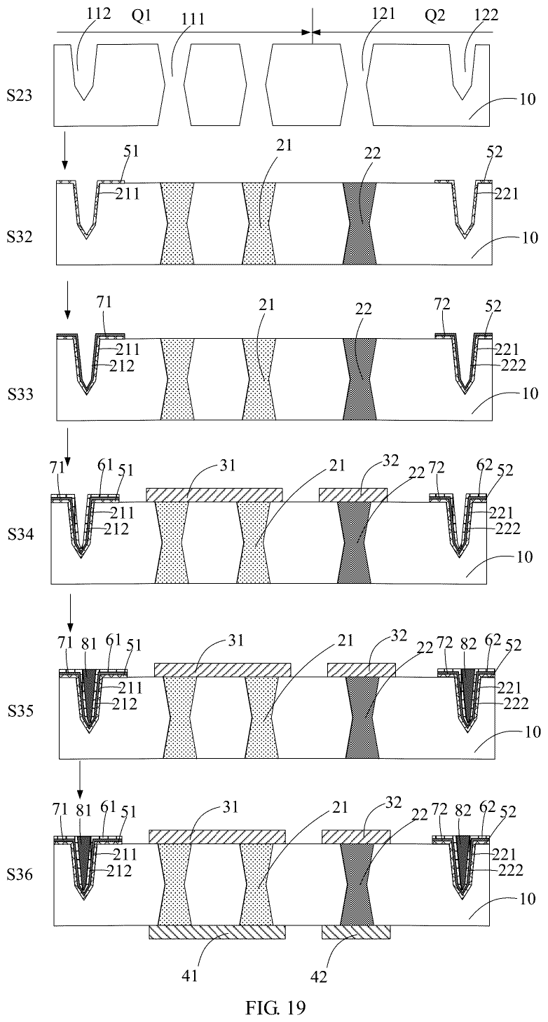

The functional substrate will be specifically described below with reference to the method for manufacturing the functional substrate. FIG. 19 is a flowchart of a method for manufacturing a functional substrate according to a third example of an embodiment of the present disclosure. As shown in FIG. 19, the method for manufacturing the functional substrate specifically includes steps S31 to S36.

At step S31, providing a dielectric substrate, wherein the dielectric substrate has a plurality of functional holes 11 which penetrate through the dielectric substrate along a thickness direction of the dielectric substrate and a plurality of anchor holes 12. The functional holes 11 are located in the central region Q1 and include a first functional hole 111 and a second functional hole 112. The anchor holes 12 are located in the peripheral region Q2 and include a first anchor hole 121 and a second anchor hole 122.

The functional hole 11 and the anchor hole 12 in the dielectric substrate are through holes, and the through holes in the dielectric substrate may be formed by any one of a sand blasting process, a photosensitive glass process, a focusing discharge process, a plasma etching process, a laser ablation process, an electrochemical process, a laser-induced etching process, and the like, which will not be described herein again.

At step S32, forming a first connection structure 21 of a first inductor in the first functional hole 111, a second connection structure 22 of a second inductor in the first anchor hole 121, a first electrode plate of a first capacitor, and a second electrode plate of a second capacitor. The first electrode plate of the first capacitor includes a first connection sub-structure 211 of the first connection structure 21 in the second functional hole 112 and a third connection electrode 51 located on the first surface and connected to the first connection sub-structure to form a one-piece structure with the first connection sub-structure. The first electrode plate of the second capacitor includes the third connection sub-structure 221 of the second connection structure 22 in the second anchor hole 122 and the seventh connection electrode 52 located on the first surface and connected to the third connection sub-structure 221 to form a one-piece structure with the third connection sub-structure 221.

In some examples, step S32 may include steps S321 to S326.

At step S321, forming a first conductive layer and a second conductive layer on the first surface and the second surface of the dielectric substrate respectively through a magnetron sputtering process, such that the first conductive layer and the second conductive layer serve as a first seed layer and a second seed layer respectively. With the formation of the first conductive layer and the second conductive layer, the inner walls of the functional hole 11 and the anchor hole 12 are each continuously covered.

At step S322, forming a first shielding structure and a second shielding structure at positions of the first seed layer corresponding to the second functional hole 112 and the second anchor hole 122, respectively. For example, attaching a dry film on a side of the first seed layer away from the second surface, and exposing and developing the dry film to form the first shielding structure and the second shielding structure.

At step S323, growing the first seed layer and the second seed layer by simultaneously applying a current to both sides of the first seed layer and the second seed layer through a double-sided plating process, so as to fill the first functional hole 111 and the first anchor hole 121.

At step S324, temporarily bonding the carrier on a side of thickened second seed layer away from the dielectric substrate; removing thickened first seed layer on the first surface through a chemical physical polishing (CMP) process; and debonding the carrier. If the carrier is thin, the temporarily bonded carrier needs to be reinforced to ensure strength.

At step S325, temporarily bonding a carrier on the first surface of the dielectric substrate; removing the thickened first seed layer on the second surface through a chemical physical polishing (CMP) process; and debonding the carrier. Similarly, if the carrier is thin, temporarily bonded carrier needs to be reinforced to ensure strength. To this end, a first connection structure 21 in the first functional hole 111 and a second connection structure 22 in the first anchor hole 121 are formed.

At step S326, removing the first shielding structure and the second shielding structure to form the first electrode plate of the first capacitor and the second electrode plate of the second capacitor.

At step S33, forming a first dielectric layer 71 of the first capacitor and a second dielectric layer 72 of the second capacitor.

In some examples, step S33 may include forming first and second dielectric layers 71 and 72 as a one-piece structure through a Chemical Vapor Deposition (CVD) process. The material of the first dielectric layer 71 and second dielectric layer 72 formed as a one-piece structure includes but is not limited to, an insulating material such as silicon oxide or silicon nitride.

At step S34, forming a first connection electrode 31 of a first inductor, a fifth connection electrode 32 of a second inductor, a second electrode plate of a first capacitor and a second electrode plate of a second capacitor on the first surface of the dielectric substrate. The second electrode plate of the first capacitor includes the second connection sub-structure 212 of the first connection structure 21 located in the second functional hole 112, and the fourth connection electrode 61 located on the first surface and connected to the second connection sub-structure 212 to form a one-piece structure with the second connection sub-structure 212. The second electrode plate of the second capacitor includes the fourth connection sub-structure 222 of the second connection structure 22 located in the second anchor hole 122, and the eighth connection electrode 62 located on the first surface and connected to the fourth connection sub-structure 222 to form a one-piece structure with the fourth connection sub-structure 222.

In some examples, step S34 may include: forming a third conductive layer through a process including but not limited to, magnetron sputtering, spin-coating a photoresist, exposing the photoresist with a mask, denaturing the photoresist by irradiating the photoresist with the ultraviolet light, developing and removing the denatured photoresist, and forming a pattern including the first connection electrode 31, the fifth connection electrode 32, the second electrode plate of the first capacitor, and the second electrode plate of the second capacitor through a wet etching process.

At step S35, the first connection structure 21 located in the second functional hole 112 defines a first recess portion, the second connection structure 22 located in the second anchor hole 122 defines a second recess portion, forming a first filling structure 81 in the first recess portion, and forming a second recess portion in the second recess portion.

In some examples, step S35 includes: forming a filling material in the first and second recess portions through a vacuum plugging process; curing the filling material; and grinding the surface flat by using an abrasive belt machine to form the first and second filling structures 81 and 82. The filler material includes but is not limited to resin.

At step S36, forming a second connection electrode 41 and a sixth connection electrode 42 on the second surface of the dielectric substrate, such that the second connection electrode 41 is electrically connected to the first connection electrode 31 through the first connection structure 21 in the functional hole 11 to form a coil structure of a first inductor, and the sixth connection electrode 42 is electrically connected to the fifth connection electrode 32 through the second connection structure 22 in the anchor hole 12 to form a coil structure of a second inductor.

In some examples, step S36 may include forming a fourth conductive layer through a process including but not limited to magnetron sputtering, spin-coating a photoresist, exposing the photoresist by using a corresponding mask, denaturing the photoresist by irradiating the photoresist with the ultraviolet light, developing and removing the denatured photoresist, and forming a pattern including the second connection electrode 41 and the sixth connection electrode 42 through a wet etching process.

With the functional substrate in the third example, since the first anchor hole 121 and the second anchor hole 122 are formed in the peripheral region Q2 of the dielectric substrate, when the three-dimensional inductor and three-dimensional capacitor are formed, the anchor hole 12 is covered with the first conductive layer and the second conductive layer, so that the separation of the first conductive layer and the second conductive layer from the dielectric substrate during the magnetron sputtering process and the electroplating process, and thereby the influence on the electrical characteristics of the three-dimensional inductor and three-dimensional capacitor due to the separation can be effectively avoided. In the third example, the anchor hole 12 is not only used for anchoring the conductive layer, but also used for forming the second inductor coil in the peripheral region Q2 while the first inductor coil is formed. While forming the first capacitor, the second anchor hole 122 is used for forming the second capacitor in the peripheral region Q2 of the dielectric substrate, which is equivalent to enlarging the device area of the functional substrate and improving the utilization rate of the dielectric substrate.

It should be noted that, only three exemplary structures of the functional substrate and the manufacturing method thereof are illustrated above, which do not limit the protection scope of the embodiments of the present disclosure. It will be understood that the above embodiments are merely exemplary embodiments adopted to illustrate the principles of the present invention, and the present invention is not limited thereto. It will be apparent to those skilled in the art that various modifications and improvements can be made without departing from the spirit and essence of the invention, and such modifications and improvements are also considered to be within the scope of the invention.

1. A functional substrate having a central region and a peripheral region surrounding the central region; wherein the functional substrate comprises:
a dielectric substrate comprising a first surface and a second surface opposite to each other in a thickness direction of the dielectric substrate; wherein the dielectric substrate has a functional hole and an anchor hole each at least penetrating through the first surface, the functional hole is in the central region, and the anchor hole is in the peripheral region; and
a first connection structure and a second connection structure, wherein the first connection structure is in the functional hole, the second connection structure is in the anchor hole, and the first connection structure and the second connection structure are made of a same material.

2. The functional substrate of claim 1, wherein
an orthographic projection of the functional hole on a plane where the first surface is located has a diameter of D; and
for the anchor hole, a distance between a center of an orthographic projection of the anchor hole on the plane where the first surface is located and a center of an orthographic projection of the functional hole on the plane where the first surface is located is not less than 2D.

3. The functional substrate of claim 1, wherein,
for the anchor hole, a minimum distance from an edge of the anchor hole to an edge of the dielectric substrate is not less than 50 μm.

4. The functional substrate of claim 1, wherein the functional hole is a through hole penetrating through the second surface; the functional substrate further comprises a first connection electrode on the first surface and a second connection electrode on the second surface; the first connection electrode is connected to the second connection electrode through the first connection structure to form a coil structure of a first inductor.

5. The functional substrate of claim 1, wherein the functional hole is a blind hole; the first connection structure comprises a first connection sub-structure and a second connection sub-structure stacked on the first connection sub-structure; the functional substrate further comprises a third connection electrode and a fourth connection electrode arranged in sequence on the first surface; the first connection sub-structure is electrically connected to the third connection electrode to form a first electrode plate of a first capacitor, the second connection sub-structure is electrically connected to the fourth connection electrode to form a second electrode plate of the first capacitor, and a first dielectric layer is between the first electrode plate and the second electrode plate of the first capacitor.

6. The functional substrate of claim 5, wherein the first connection structure in the functional hole defines a first recess portion, a first filling structure is filled in the first recess portion, and a surface of the first filling structure away from the second surface is flush with a surface of the fourth connection electrode away from the second surface.

7. The functional substrate of claim 1, wherein the functional hole comprises a first functional hole and a second functional hole; the first functional hole is a through hole penetrating through the second surface; the second functional hole is a blind hole; the functional substrate further comprises first, third, and fourth connection electrodes on the first surface, and a second connection electrode on the second surface;
the first connection electrode is connected to the second connection electrode through a first connection structure in the first functional hole to form a coil structure of a first inductor; and
the first connection structure in the second functional hole comprises a first connection sub-structure and a second connection sub-structure stacked on the first connection sub-structure; the first connection sub-structure is electrically connected to the third connection electrode to form a first electrode plate of a first capacitor, the second connection sub-structure is electrically connected to the fourth connection electrode to form a second electrode plate of the first capacitor, and a first dielectric layer is between the first electrode plate and the second electrode plate of the first capacitor.

8. The functional substrate of claim 7, wherein the first connection structure in the second functional hole defines a first recess portion, a first filling structure is filled in the first recess portion, and a surface of the first filling structure away from the second surface is flush with a surface of the fourth connection electrode away from the second surface.

9. The functional substrate of claim 1, wherein the anchor hole is a through hole penetrating through the second surface; the functional substrate further comprises a fifth connection electrode on the first surface and a sixth connection electrode on the second surface; and the fifth connection electrode is connected to the sixth connection electrode through the second connection structure to form a coil structure of a second inductor.

10. The functional substrate of claim 1, wherein the anchor hole is a blind hole; the second connection structure comprises a third connection sub-structure and a fourth connection sub-structure stacked on the third connection sub-structure, the functional substrate further comprises a seventh connection electrode and an eighth connection electrode arranged in sequence on the first surface; the third connection sub-structure is electrically connected to the seventh connection electrode to form a first electrode plate of the second capacitor, the fourth connection sub-structure is electrically connected to the eighth connection electrode to form a second electrode plate of the second capacitor, and a second dielectric layer is between the first electrode plate and the second electrode plate of the second capacitor.

11. The functional substrate of claim 10, wherein the second connection structure in the anchor hole defines a second recess portion, and a second filling structure is filled in the second recess portion; a surface of the second filling structure away from the second surface is flush with a surface of the eighth connection electrode away from the second surface.

12. The functional substrate of claim 1, wherein the anchor hole comprises a first anchor hole and a second anchor hole; the first anchor hole is a through hole penetrating through the second surface, and the second anchor hole is a blind hole; the functional substrate comprises fifth, seventh, eighth connection electrodes on the first surface, and a sixth connection electrode on the second surface;
the fifth connection electrode is connected to the sixth connection electrode through a second connection structure in the first anchor hole to form a coil structure of a second inductor; and
a second connection structure in the second anchor hole comprises a third connection sub-structure and a fourth connection sub-structure stacked on the third substructure; the third connection sub-structure is electrically connected to the seventh connection electrode to form a first electrode plate of a second capacitor, the fourth connection sub-structure is electrically connected to the eighth connection electrode to form a second electrode plate of the second capacitor, and a second dielectric layer is between the first electrode plate and the second electrode plate of the second capacitor.

13. The functional substrate of claim 12, wherein the second connection structure in the second anchor hole defines a second recess portion, and a second filling structure is filled in the second recess portion; a surface of the second filling structure away from the second surface is flush with a surface of the eighth connection electrode away from the second surface.

14. The functional substrate of claim 1, wherein the dielectric substrate comprises glass.

15. A method for manufacturing a functional substrate having a central region and a peripheral region surrounding the central region; wherein the method comprises:
providing a dielectric substrate having a first surface and a second surface opposite to each other along a thickness direction of the dielectric substrate;
forming a functional hole and an anchor hole in the dielectric substrate such that the functional hole and the anchor hole at least penetrate through the first surface, the functional hole is in the central region, and the anchor hole is in the peripheral region; and
forming a first connection structure in the functional hole and a second connection structure in the anchor hole.

16. The method of claim 15, wherein the functional hole is a through hole; the functional substrate comprises a first inductor in a central region, and
the method further comprises forming the first inductor, and forming the first inductor comprises forming the first connection structure in the functional hole; forming a first connection electrode on the first surface of the dielectric substrate; forming a second connection electrode on the second surface, such that the first connection electrode is connected to the second connection electrode through the first connection structure to form a coil structure of the first inductor.

17. The method of claim 15, wherein the functional hole is a blind hole; the functional substrate comprises a first capacitor in the central region, and the method further comprises forming the capacitor, and forming the capacitor comprises: sequentially forming a first electrode plate, a first dielectric layer and a second electrode plate on the first surface; and
forming the first connection structure comprises sequentially forming a first connection sub-structure and a second connection sub-structure on the first surface such that the first connection sub-structure serves as a portion of a first electrode plate of the first capacitor, and the second connection sub-structure serves as a portion of a second electrode plate of the first capacitor.

18. The method of claim 17, wherein after forming the second electrode plate of the first capacitor, the method further comprises:
filling a first filling structure in a first recess portion, wherein the first recess portion is defined by the first connection structure in the functional hole.

19. The method of claim 15, wherein the anchor is a through-hole; the functional substrate comprises a second inductor in the central region, the method further comprises forming the second inductor, and forming the second inductor comprises: forming the second connection structure in the anchor hole; forming a fifth connection electrode on the first surface of the dielectric substrate; forming a sixth connection electrode on the second surface, such that the fifth connection electrode is connected to the sixth connection electrode through the second connection structure to form a coil structure of the second inductor.

20. The method of claim 15, wherein the anchor is a blind hole; the functional substrate comprises a second capacitor in the central region, and the method further comprises forming a second capacitor, and forming the second capacitor comprises: sequentially forming a first electrode plate, a second dielectric layer and a second electrode plate on the first surface; and
forming the second connection structure comprises: sequentially forming a third connection sub-structure and a fourth connection sub-structure on the first surface; such that the third connection sub-structure serves as a portion of the first electrode plate of the second capacitor, and the fourth connection sub-structure serves as a portion of the second electrode plate of the second capacitor.
